(19) United States
(12) Patent Application Publication
(10) Pub. No.: US 2005/0063441 A1
(43) Pub. Date: Mar. 24, 2005

(54) High density methods for producing diode-pumped micro lasers

(76) Inventor: David C. Brown, Brackney, PA (US)

Correspondence Address: Thomas M. Freiburger, P.O. Box 1026, Tiburon, CA, 94120, US

(21) Appl. No.: 10/946,941

(22) Filed: Sep. 22, 2004

Related U.S. Application Data
(60) Provisional application No. 60/504,617, filed on Sep. 22, 2003.

(51) Int. Cl. H01S 5/00; H01S 3/091

(52) U.S. Cl. 372/50; 372/75; 372/43

(57) ABSTRACT

A miniaturized laser package is provided comprising a standard semiconductor laser package modified to accept a solid state microchip assembly pumped by the diode laser. Standard packages described in the invention include TO and HHL packages all of which are characterized by small dimensions, well sealed housing, robust mounting features, known characterized materials and economical production and assembly techniques characteristic of the semiconductor processing industry. In particular, the microchip lasers are produced using high density techniques that lend themselves to mass production, resulting in very low unit costs. At the same time, the compact laser devices provide a solution to the problem of providing laser radiation at high beam quality and good reliability features with a variety of wavelengths and operational characteristics and low noise features not available from diode lasers yet relying primarily on standardized designs, materials and techniques common to diode laser manufacturing. The devices constructed according to methods taught by the invention can therefore be readily integrated into numerous applications where power, reliability and performance are at a premium but low cost is essential, eventually replacing diode lasers in many existing systems but also enabling many new commercial, biomedical, scientific and military systems.

This application claims the benefit of priority from Provisional U.S. Patent Application Ser. No. 60/504,617 filed Sep. 22, 2003.

### FIELD OF THE INVENTION

The present invention relates to highly compact and/or miniaturized diode pumped solid state lasers that are manufacturable using mass production techniques.

### BACKGROUND OF THE INVENTION

New types of microlasers are desired as a replacement for conventional red lasers, particularly red semiconductor diode lasers that are commonplace in many applications including pointing devices, supermarket scanners, gun pointers, and others. While diode lasers can provide wavelength coverage in the blue, red, and near infrared regions, currently no diode laser technology can produce green wavelengths with any substantial output power. Yet, the green wavelength region is particularly important because it is the region where the spectral responsivity of the human eye is a maximum and where underwater transmission peaks. In addition, diode lasers are typically low-brightness devices with an astigmatic output due to the disparity in divergence angles in the directions parallel and perpendicular to the diode stripe. On the other hand, solid state lasers—even compact modern diode-pumped, versions—tend to be too bulky and/or expensive to be used in mass applications such as supermarket scanners or for writing compact disks. Furthermore, solid state lasers tend to emit their fundamental radiation in the infrared region of the spectrum near and around 1 μm, and additional means must therefore be incorporated in the laser to produce light in the visible.

These means generally comprise one or more nonlinear processes. For example, a second-harmonic-generation (SHG) process can be used to convert the 1064 nm transition in Nd doped YAG or YVO₄ (vanadate), to an output wavelength at 532 nm, using a suitable nonlinear crystal. More generally, sum-frequency-generation (SFG) can be applied to sum the frequencies of two different laser wavelengths. The most common application of SFG is third harmonic generation (THG), where an infrared and a green photon are added to produce UV radiation, for example at 355 nm in the Nd-doped materials mentioned above. Alternatively, different transitions from the same material can be summed to produce still other wavelengths. In addition to SHG and SFG there are other nonlinear processes that can be used to produce other discrete wavelengths using fixed laser transitions, including optical parametric amplification (OPA), and Raman shifting. Whereas techniques and materials are known that can be used to generate a variety of wavelengths from solid state lasers across the visible spectrum, the nonlinear techniques thus can greatly expand the range of wavelengths available from a single solid state laser crystal. However, these means all tend to add bulk and cost to the systems, even when simple diode pumped designs are utilized. This is particularly true for green lasers designed to run in a single-transverse (Gaussian) mode (STM) and/or single-longitudinal mode (SLM).

There are two generic ways to frequency-double a laser, known as external (extracavity) or internal (intracavity). We note that “cavity” and “resonator” are used interchangeably to describe an optical resonator. In the extra-cavity doubling case, a beam from a laser source is passed through a nonlinear crystal with some of the beam's energy converted to green output. There are known limitations to any extracavity nonlinear process that tend to limit the efficiency of harmonic conversion—especially where high peak powers are not available, as in the case of, e.g., CW lasers where SHG efficiencies are generally less than 5%. By contrast, considerably higher efficiencies may be obtained for intracavity conversion, where the nonlinear crystal is placed internal to the resonator, because the intensity of the fundamental beam inside the resonator is significantly larger than in the extra-cavity case. The intra-cavity frequency doubled configuration is therefore the one most commonly used for lower power and/or cw lasers.

Shown in FIG. 1 is a generic intra-cavity doubling configuration that is directly applicable to gain materials such as Nd:YAG (yttrium aluminum garnet) or Nd:YVO₄ (orthovanadate) which have a fundamental laser transition near 1064 nm and are optically pumped by radiation at or near 808 nm. The pump radiation is supplied by a semiconductor laser, which may comprise, in various embodiments, a direct coupled diode laser, fiber-coupled diode, or a diode array. Alternatively, the Nd laser transition may also be pumped directly at the longer wavelengths of 869 or 885 nm. Laser light generated at the laser wavelength—in this case at 1064 nm—is optically “trapped” inside the resonator when highly reflective coatings are used at each end of the resonator. To allow for more compact cavities, at least one end of the resonator may be defined by the laser gain material itself. In the example of FIG. 1, the laser material facing towards the diode or diode array is coated so it is highly transmissive (HT) at the pump wavelength, and highly reflecting (HR) at the laser wavelength. The lasing crystal's opposite face is typically anti-reflection (AR) coated at the fundamental wavelength of 1064 nm and also at 532 nm if the laser is intra-cavity doubled. In this case, the optical resonator is formed between the rear surface of the lasing crystal (facing the diode) and the outcoupler. The outcoupler, which may, in different embodiments have a curved or a flat surface facing the diode, is typically a partial reflector (PR) if the 1064 nm transition is lased, or is coated for HR at 1064 nm and HT at 532 nm if intra-cavity SHG is implemented. The output surface of the outcoupler is usually AR coated at the second harmonic wavelength for intracavity doubled laser configuration. For a stable optical resonator a planar output coupler may be used if the thermal lensing imparted to the lasing material by the absorbed pump radiation is sufficient to assure TEM₀₀ operation. Alternatively, the output surface of the outcoupler can be curved in order to maintain resonator stability. The curvature may be further adapted to diverge or collimate the output laser beam, as needed.

Because the outcoupling at 1064 nm in the intracavity doubling case is nil, approximately equal intensities of the fundamental radiation circulate inside the resonator, to the right and to the left. This results in the build up of a high 1064 nm CW intensity inside the resonator. Each fundamental beam generates a green beam traveling in the same direction. Since the fundamental beam inside the resonator travels in both the +(right) and − (left) directions, green second-harmonic beams are also generated in both directions. If the outcoupler is coated for HT at the second harmonic wavelength, the green light traveling to the right exits the resonator. Green light traveling to the left is reflected back to the right from the 532 nm HR coated surface on the side of the lasing crystal facing the diode and subsequently also leaves the resonator through the outcoupler, co-linear with the right traveling green beam. In spite of the fact that there is usually some finite absorption at the second harmonic wavelength in the lasing crystal, collecting the backward (left) traveling green light results in a substantial improvement in the green conversion efficiency. If high quality optics and crystals are used, even for CW operation the intensity generated in the resonator is sufficient to result in 15-30% conversion efficiencies from diode output to green output. Still higher conversion efficiencies can be achieved for pulsed operation, in which case a Q-switch is typically included in the cavity.

It is noted that the basic configuration shown in FIG. 1—whether pulsed or CW—is well known in the art of constructing diode pumped intracavity frequency doubled lasers. It is also understood that although the embodiment of FIG. 1 was specific to the main transition of Nd:YAG or Nd:YVO₄ at 1064 nm, similar principles apply to other transitions in these or other laser materials. For example, alternative transitions that can be lased include the ones at the 946 nm or the 1319 nm for Nd:YAG and the corresponding transitions at 914.5 nm and 1342 nm in Nd:YVO₄. Intracavity conversion of the ⁴F_{3/2}→⁴I_{9/2} in Nd doped lasers into the blue was taught in the early U.S. Pat. No. 4,809,291 to Byer et al and a monolithic version of intracavity doubled Nd doped vanadate laser was described in U.S. Pat. No. 5,574,740 to Hargis and Nelte. Other Nd-doped materials, such as Nd:YLF or Nd:YALO can also be employed in an intracavity configuration similar to FIG. 1 with laser action selected at the fundamental or at an alternate transition. One important modification to the cavity of FIG. 1 when selecting an alternate lower gain transition, is that the corresponding HR coatings on the various surfaces must also have a minimum reflectivity at the fundamental line in order to suppress that dominant transition.

The laser material may also be fabricated in a number of geometries. For example, it can be machined as a thin plate (a disc) or a long rod. Selection of the gain material geometry is generally dictated by considerations of pump absorption efficiency, available concentration, material properties and heat removal requirements. Typically, a thin plate configuration is preferred from a thermal viewpoint but there is often a trade-off against absorption length and the optimal geometry may differ for different gain materials.

For microlaser structures, intra-cavity doubling is relatively simple to implement and is often more efficient than extra-cavity doubling arrangements. The prior art recognizes a number of techniques and approaches to fabricating compact, frequency converted miniaturized solid state lasers. For example, U.S. Pat. No. 6,111,900 teaches a method wherein a laser crystal and a nonlinear crystal are connected and combined by a spacer. This type of laser assembly is however labor-intensive to produce and relatively expensive. SLM operation was realized through the concept of microchip lasers as taught by U.S. Pat. No. 4,860,304 to Mooradian and subsequent patents U.S. Pat. Nos. 4,953,166, 5,265,116, 5,365,539, and 5,402,437, which relied on selecting the cavity length so as to keep the gain bandwidth of the active medium always smaller than or equal to the frequency separation of the cavity modes. Whereas Mooradian taught the use of transparent optical cement to bond laser and nonlinear materials, the bonding techniques of the monolithic structures did not allow for joining coated surfaces and the stringent requirements placed on cavity lengths produced lasers that were susceptible to mode hopping noise and were, in practice, difficult to fabricate efficiently with the desired quantities, production economies and costs. Subsequent methods for achieving SLM operation from microchip lasers, included various constructions such as the one described by Shimoji in U.S. Pat. No. 6,026,102 where angled surfaces form an air space etalon between the laser material and nonlinear crystal so as to produce SLM operation. Such an approach may again require more sophisticated fabrication techniques that may require separate processing for each microchip composite, making the process more difficult to apply to a mass production environment.

Alternative techniques to construct a monolithic laser assembly comprising a laser medium and a nonlinear crystal include the method of “contact bonding” as used for example by one crystal manufacturer, VLOC Inc. FIG. 2 represents the intracavity frequency doubled microlaser resonator configuration commercially offered by VLOC Inc. As shown, the assembly is pumped from the left by a diode beam at or near 808 nm and the green beam emerges from the right face of the nonlinear material. This configuration is often referred to as a flat-flat resonator, and in the sense understood by laser designers, is unstable. However, because all lasing elements exhibit thermal lensing, or gain-guiding effects in the crystals can be exploited to obtain stable operation. In this example, the laser consists of a monolithic crystal assembly comprising a Nd-doped laser crystal (typically Nd:YAG or Nd:YVO₄) optically contacted to a nonlinear frequency doubling crystal (typically KTP), with the assembly end surfaces coated to maximize the green output. To form the resonator, the left Nd:YVO₄ surface is coated to be HT around the diode pump wavelength at around 808 nm and HR at 1064 nm and 532 nm, while the right KTP surface is coated to be HR at 1064 nm and HT at 532 nm and it serves as the outcoupler of green radiation. The internal contact-bonded surfaces are typically uncoated and there exists a small reflective loss due to the index of refraction difference between the Nd:YVO₄ and the KTP crystals. As is customary in the art of constructing a frequency doubled Nd:YVO₄ laser, the Nd:YVO₄ c axis is rotated by 45° with respect to the KTP oriented for Type II phase matching direction defined by the crystalline angles θ=90° and typically φ=23°. When completed, the crystal assembly is quite compact, the KTP crystal having dimensions of 5 mm×5 mm×1.5 mm thick, and the Nd:YVO₄ having dimensions of 3 mm×3 mm×0.4 mm, according to the manufacturer's literature. Like the microlaser of Mooradian et al, the short cavity length means that this assembly is capable of operating in a SLM and/or STM over some limited power range. The laser can also be run STM by creating an appropriate diode-pumped excitation spot-size in the assembly. The method of contact bonding comprises placing the elements to be bonded in close optical proximity, resulting in a strong Van der Walls attraction between the surfaces. The contact is typically sealed around the edges of the bond using a glue such as methylacrylate. While optically robust, the method of contact bonding individual crystals is, however, still rather expensive, with cost and yield issues. Moreover, it is further recognized that with this type of monolithic laser assembly, the actual laser uses only a small fraction of the available crystals' volume. In typical green and infrared laser devices for example, a section only 100-200 μm of the central region of the crystal is used. The remaining portion of expensive crystal material is thus wasted making it difficult to further minimize the materials cost of each completed assembly. Further cost reductions with this prior art technique are made difficult by the fact that is not practicable to make contact-bonded crystal assemblies much smaller because of difficulties associated with contacting small area surfaces together. With current fabrication technologies, it is therefore difficult to reduce the unit cost, which tends to exceed $1000.00 per unit.

Other alternate technologies for producing miniaturized lasers operating in the visible include frequency-doubled VCSEL (Vertical Cavity Surface Emitting Lasers) structures either externally or internally as described, for example, in recent U.S. Pat. Nos. 6,614,827 and 6,243,407. Such semiconductor based devices tend, however, to have relatively high costs of production, requiring major investment in processing facilities and are limited in their output wavelengths to those that can be efficiently produced by semiconductor quantum well structures. Thus, visible lasers based on the VCSEL architecture are generally still too bulky and costly to meet the needs of mass applications such as pointers, supermarket scanners and construction aids, which rely at present on diode lasers priced at less than $100 a unit.

The prior art recognizes a number of other attempts to construct compact diode pumped laser packages. Alternative approaches utilizing diode pumped solid state laser with or without frequency conversion include packaging the laser medium in a TO semiconductor device as was described for example by Mori et al in U.S. Pat. No. 5,872,803. The package described in this patent relies however on mechanical mounting techniques in a relatively bulky TO3 package which is typically 1×1×1.5 inches long (including a TE cooler). Mechanical adjustments can however, result, in stresses to the optical components, compromising alignment and output stability properties, especially if nonlinear elements are to be included in the cavity.

Clearly, methods for fabricating and producing low-cost, high-density (watts of output power divided by the device volume) micro laser devices, and in particular micro laser devices operating in the green spectral region near 532 nm must still be found. In particular, for the consumer market, there is a need for laser packages that can produce visible light at sufficient powers yet are small enough and have sufficiently low unit costs to be able to compete with semiconductor lasers. There is also still a need to be able to produce miniaturized lasers that can be adapted to operate at a variety of wavelengths in the UV through the infrared for applications such as biomedical instrumentation. For many applications, it is also important that manufacturing and operational costs remain low even for high end applications where reliable SLM and/or STM operation is required with low noise characteristics.

### SUMMARY OF THE INVENTION

This invention addresses methods for producing high-density low-cost micro and miniature laser resonators capable of providing high beam quality laser radiation that can be assembled in highly compact packages using fabrication methodologies compatible with mass production and low unit costs (<$100.). The techniques and methods described in this disclosure thus provide solutions to the challenge of designing for manufacturability using mass production techniques characterized by their simplicity, cost effectiveness and adaptablity to operation at many different modes and a variety of wavelengths in either the visible or beyond. The invention further emphasizes those packaging technologies, fabrication processes, laser designs and materials that can provide high performance without compromising reliability of the microlaser devices, all with per unit materials' cost that can be as low as less than a few $100's even for more complex microchips. This makes the miniature devices produced according to the principles of the invention suitable to be integrated into numerous applications including those in the consumer and biomedical markets, potentially supplanting and replacing existing diode laser technology. The techniques disclosed also lend themselves to microlasers that can produce radiation at a large variety of operational modes and wavelengths. Specifically, the present invention provides improved methods, systems, and devices for providing cost effectively operational modes that include SLM in both CW and pulsed versions and spectral ranges that extend into the eyesafe regime on one end and the UV on the other.

In one aspect of the invention, a miniaturized diode pumped solid state laser is provided in a package adapted from a standard semiconductor TO package by extending a shelf directly from the diode laser's mounting platform requiring modification of only the length of the housing cap. A gain crystal assembly which includes at least one active laser material is affixed to the shelf following alignment and optimization of the output. The gain crystal assembly is generally disposed within a resonator comprising at least two mirrors wherein one or both mirrors may be directly deposited as a coating on the crystal assembly's faces. The TO package dimensions may be selected to correspond to any standard semiconductor package including specifically the 9 mm and 5.6 mm packages, with the type of package generally determined by the diode power requirements. At the highest power levels or when greater complexity of the output are required, the designs and methods of the invention may be extended to HHL packages which incorporate more advanced cooling features.

In another aspect of the invention, the package may include additional features and/or optical elements designed to produce different operational features from one standardized, mass producible package. These features include means for controlling the power, spatial beam quality, bandwidth and wavelength of the output. For example, in one embodiment, the diode may include Bragg gratings used to lock and stabilize its wavelength. This can translate into lower noise and greater output stability from the microlaser. In other embodiments, the temperature of the diode as well as the gain crystal assembly may be independently controlled and adjusted using heat sinks and TEC's. In still another aspect of the invention, the entire package may be mounted on an external cooler to provide improved performance at higher powers.

An object common to all the embodiments encompassed by the invention is to provide gain crystal assemblies using high density manufacturing techniques. Whether a simple composite made of only two optical elements or a more complex assembly including several different elements, material bonding techniques and assembly fabrication technologies are selected that allow a large number of crystal gain assemblies to be fabricated from a single composite wafer by simple dicing, thereby reducing the unit costs to potentially below $100. per assembly.

It is a specific object of the invention to be able to provide output powers of over 30 mW in the visible from packages that have volumes of less than 1 cm3, a feature, not previously possible with available prior art techniques and fabrication methodologies. With specialized heat sinking of the gain crystal assembly, over 150 mW were demonstrated in the green from a modified 9 mm package, using monolithic resonators of Nd:YVO₄/KTP crystal composites with excellent beam quality and high stability features of the output.

It is yet another object of the invention to produce pulsed output from the microlasers manufactured and fabricated according to the high density methods disclosed. In one embodiment laser beams from the UV to the infrared can be produced with nanosecond pulse durations and high repetition rates as required for numerous applications in biotechnology, fiber laser seeding and military technologies. The small size and low cost of the pulsed devices allow ready integration into systems, much in the same way as is currently done with semiconductor lasers.

Many prior art techniques such as are well know in the art of laser design may be beneficially and readily incorporated in the packaging techniques taught in this inventions. These designs include a variety of frequency conversion techniques such as harmonic generation, Raman conversion and optical parametric oscillation. The only limitation on use of these processes are the availability of nonlinear materials in sufficiently large sizes and good enough quality to allow them to be incorporated in composite wafers that can be bonded, polished and fabricated using high density techniques.

In another aspect, some of the more advanced high end device embodiments may incorporate feedback loops and sensors integrated in the package as is often done in semiconductor lasers—to thereby provide additional control means of the output. The ability to adapt and integrate known features and elements of semiconductor laser technology is a key advantage of the techniques and methods of the invention, enabling maximum operational flexibility at the lowest unit prices from very compact packages.

A further understanding of the nature and advantages of the invention will become apparent by reference to the remaining portions of the specification and drawings.

### BRIEF DESCRIPTION OF THE FIGURES

FIG. 1 is a schematic of Intracavity Frequency-Doubling (Prior Art).

FIG. 2 illustrates the Bonded VLOC Chip Resonator (Prior Art).

FIG. 3 shows the configuration of a Solid State Microlaser mounted in a Modified diode laser TO package.

FIG. 3A provides a view of the configuration and components of a standard 9 mm TO Diode Laser Package (Prior Art).

FIG. 4 is another example of a Microlaser modified TO package including a Discrete Outcoupler.

FIG. 5 is an example of a Gain Crystal Assembly with two cemented optical elements.

FIG. 6 illustrates elements of the High density Crystal Fabrication Technique.

FIG. 7 illustrates a Crystal Gain Assembly configured with a Discrete Curved Outcoupler and suited for intracavity SHG.

FIG. 8 is an example of Crystal Gain Assembly with three optical elements suited for Third or Fourth Harmonic Generation.

FIG. 9 is an example of a Microchip Laser resonator including a gain medium and a Q-switch suitable for producing pulsed radiation.

FIG. 10 shows a Schematic of a Gain Crystal Assembly that can be used to produce Q-Switched Frequency converted radiation from a modified diode laser package.

FIG. 11 is one example of a gain Crystal Resonator Assembly comprising a Passively Q-Switched Eye-Safe Microlaser.

### DETAILED DESCRIPTION OF THE INVENTION

In order to construct miniature high-density low cost lasers three key design and processing aspects must be addressed. These are packaging, crystal fabrication and resonator design. The present invention incorporates unique features in each of these areas that allow various combinations of materials and components to be fabricated so as to address a wide range of operational modalities, but all sharing the common feature of compatibility with miniaturized, low cost, mass producible devices. Turning our attention to the three key design aspects these are discussed separately next.

1. Packaging:

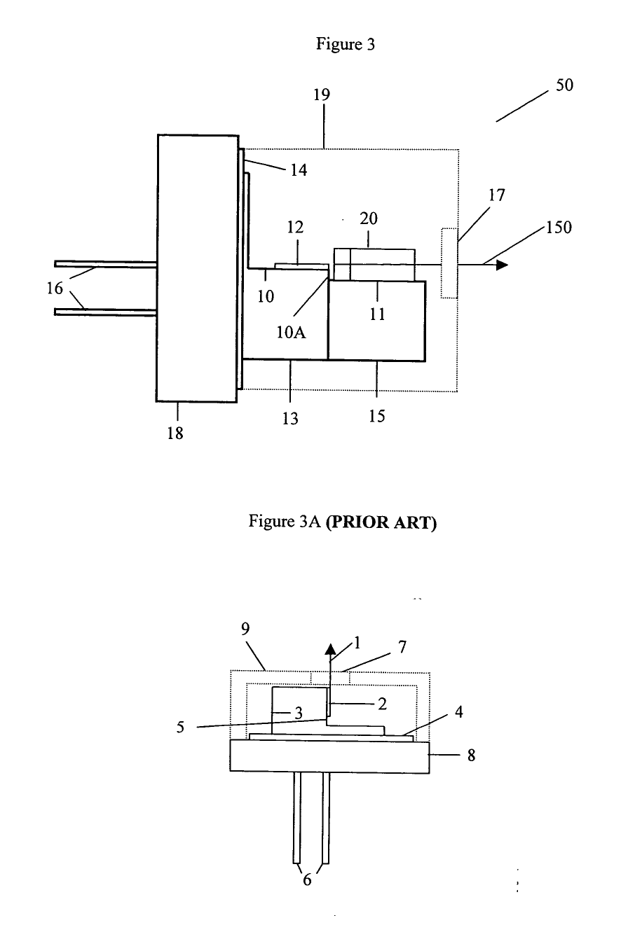

In order to package microchips into useful and mass-producible devices it is important to have a package, that will serve to minimize the overall laser volume while providing the functionality required for laser operation and the low costs associated with mass applications. In one preferred embodiment, a standard diode TO (transistor outline) package is modified to accommodate a micro solid state laser as shown in FIG. 3. For illustrative purposes, the “9 mm package” is shown in inset 3A of FIG. 3 as this configuration is known to set the standard for packaging commercial diode laser products used in the diode laser industry, and is also known as SOT 148. The package generally comprises pedestal 8 with a maximum outside diameter of 9 mm, typically fabricated using CU/W alloy, containing electrical leads 6. The two leads shown are isolated from the package body, typically by means of metal to glass seals. A third lead (not shown in the inset 3A) provides a ground for the body. A mounting platform 3 attached to the pedestal through a ridge 4 provides a surface 5 on which diode 2 can be mounted. The ridge 4 generally provides a circular means for centering of the cover (or cap) 9 prior to securing it to the pedestal. In some packages, the platform 3 may include a suitable TEC cooler if active cooling of the diode is required. In most standard packages, the cover 9 is hermetically sealed in order to isolate the diode package from the environment, thereby protecting any sensitive interior structures. A transparent window 7 is embedded in the cover to allow transmission of output beam 1 emitted by diode 2. The window 7 is usually attached to the sealed cover 9 using standard metal to glass sealing techniques.

In one preferred embodiment, the inventive configuration 50 of FIG. 3 is designed as a deriviative of the standard semiconductor laser TO package, comprising a similar circularly symmetric pedestal 18 connected to platform 13 through a ridge 14. The maximum outside diameter of the pedestal determines the type of TO package, e.g., 9 mm for a “modified 9 mm package”, 5.6 mm for a modified “5.6 mm package” etc. The pedestal may be fabricated generally using the same Cu/W alloy used for the standard package with electrical power introduced through similar leads represented as 16. The platform 13 provides a surface 10 on which diode 12 can be mounted, similar, again to the standard package of FIG. 3A. This mounting platform can be fabricated “in place” as part of the package fabrication process, eliminating the step of separately attaching the platform to the package. In one preferred embodiment of the package designed to accept the miniature or microchip lasers (alternately referred to as “microlaser”) of the present invention, the platform or mount 13 is extruded and another shelf 15 is created with a surface 11 on which to mount the micro laser assembly 20. Surfaces 10 and 11 on which the diode pump and microchip laser assembly are respectively mounted may be vertically offset from each other. This allows the diode 12 to be properly aligned at the edge 10A of the mounting surface 10, while pumping the center of the microchip laser crystal assembly 20. In the example shown in FIG. 3 the diode-to-microchip energy transfer is achieved by way of a simple butt-coupling of the gain medium to the diode output facet. To obtain good laser efficiency with this scheme, it is important to minimize the air gap between the diode and the crystal assembly 20. Preferably the gap is less than about 1-2 μm thick. While this butt-coupling approach is the simplest, alternative coupling techniques using various lens combinations are also feasible as will be further described below.

As in the standard TO package, the laser emission 150 takes place in a direction such that it passes through custom output window 17 which is attached to a sealed cover 19 using metal to glass sealing techniques as are well known in the art of diode laser butterfly packages. The output window 17 may be fabricated from one of many optically transmissive materials, such as sapphire, fused silica, or glass, including optical glass that is absorptive at the fundamental wavelength at 1064 nm and transmissive at the doubled green wavelength of 532 nm. Advantageously, the window may also be coated on one or both faces using AR coatings appropriate to the wavelength of the output beam 150 in order to reduce Fresnel reflection losses. The coatings on one or both surfaces may be designed to reflect 1064 nm light and transmit 532 nm light. The entire cap or cover 19 for the package is used to effectively seal the laser from the environment and may be welded to pedestal 18 after diode and micro laser installation to provide a true hermetic seal. Alternatively, it may be glued down to provide a quasi-hermetic seal. Circular ridge 14 can be again used to define the center of the circularly symmetric cap 19 in a manner similar to well known procedures used in assembling standard diode packages, including the common 9 mm and 5.6 mm configurations.

In fabricating this laser package, a small drop of optical cement is applied to shelf 11 and the microchip crystal assembly 20, which may be wrapped in an appropriate protective heat sink, is then placed on top of the shelf. The cement assures that the complete microchip assembly will be stably affixed to the mounting structure. The crystal assembly is then aligned to the pumping diode and any other optical elements in the package using appropriate precision alignment tooling. Once alignment is achieved, a UV lamp can be used to harden the cement and the microchip laser is then precisely and stably aligned. Alternatively, crystals may also be securely affixed to the shelf using standard soldering techniques. The length of shelf 15 generally depends on the type of the microchip laser assembly and resonator design. Various derivatives of the general package of FIG. 3 with shelf lengths of anywhere between a few mm's to just over 10 mm could be constructed to readily accommodate any commercially available diodes with powers up to a maximum dictated by heat removal considerations, as will be further discussed below. In one example, with a basic monolithic configuration of the microchip assembly 20 comprising one or two elements, a resonator is defined solely by appropriate coatings placed on the two external faces of gain crystal assembly so that the output beam is produced without inserting any additional optical elements. In this case, shelf 15 can be as short as 2-4 mm.

Generally, the 9 mm package has been found appropriate for running diodes up to 2 W output power, although special cooling methods may be required to efficiently remove the heat for diodes with powers in excess of 1 W. Most of the microlaser resonator embodiments described in the invention are compatible with pumping by diodes with power outputs of 1 W or less, allowing the 9 mm package to be utilized without any special cooling provisions. Of course, lower power diodes can be employed in scaled-down versions of the packaging concept of FIG. 3 to thereby meet the needs of applications requiring lower power devices. More specifically, modified versions of the standard 9 mm can be configured and specifically adapted to standard 5.6 mm, 8:32 and 10:32 diode packages, known in the semiconductor laser industry. Of these, the 5.6 mm package, also known as TO-18, is of particular interest as it is another common industry standard. Although the smaller 5.6 mm diameter provides more limited thermal dissipation properties as compared with the larger size packages, it may still be used effectively with diode output powers as high as 500 mW. Appropriately modified versions of this package may thus provide a suitable platform for low power versions of the micro lasers of the present invention. Both the 9 mm or 5.6 mm packages minimize the overall laser volume and the selection among them depends on the output power and laser mode desired. In preferred embodiments, the total volume of the microlaser package is less than about 1 cubic centimeter, considerably less than any of the prior art packages. It should however be understood that any other standard semiconductor packages or custom derivatives thereof also fall within the scope of the invention. In particular, derivatives of larger standardized semiconductor-base packages such as the TO-3, TO-5 and high-heat-load (HHL) may be used in still higher power versions of compact diode pumped lasers, subject to the mass producibility principles embodied in this disclosure.

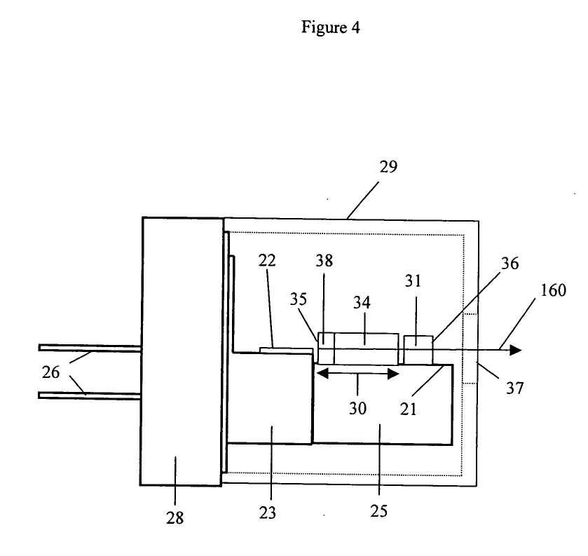

It is further recognized that, generally, in order to produce higher powers, a discrete outcoupler may need to be included in the package so as to facilitate alignment of components and allowing stable and reliable operation at a range of power levels, up to the maximum specified power. Furthermore, it may be of particular interest to enable operation at a wavelength other than the fundamental excitation of the gain material. An example of alternative embodiment suited to obtaining higher powers from a frequency converted diode pumped micro laser, is illustrated in FIG. 4. The configuration 60 represents a modification of the standard package of FIG. 3 comprising a diode pumped microchip crystal assembly but with an additional output coupler 31 defining the exit face 36 of the laser resonator. In this illustrative example, the microchip laser assembly 30 is shown consisting of two elements: a gain laser element 38 and a nonlinear optical element 34 combined in a single monolithic assembly. The nonlinear optical element is typically selected to convert the frequency of the fundamental output produced by the gain medium 38 to some other desired output frequency. The back face 35 of gain element 38 facing the diode 22 is appropriately coated to provide high transmission of the diode pump wavelength and high reflection at the resonating and frequency converted wavelengths, serving as the back HR mirror for the laser resonator The outcoupler 31 is then coated to transmit the frequency converted beam 160 to thereby provide maximum power at the converted wavelength. To eliminate any Fresnel losses, window 27 embedded in the extended cover 29 may be AR coated for the same output output wavelength. In some cases, such as when the nonlinear element 34 is a second harmonic generation crystal, one or both of the window surfaces may have a coating which is HR at the fundamental wavelength thus further minimizing the fraction of light transmitted at any wavelength other than the desired one at the converted wavelength. In one preferred embodiment, the microlaser gain assembly comprises a Nd doped gain crystal emitting at 1064 nm, such as Nd:YVO4 or Nd:YAG and the nonlinear element is a doubler crystal such as KTP or LBO. In this case the resonator defined by mirrors 35 and 36 is designed to emit green light at 532 nm and the coatings on all the surfaces are selected accordingly. Any other known gain and nonlinear crystal combinations may however be selected and the microlaser package 60 is therefore adaptable to produce a large variety of wavelengths, spanning the UV into the infrared spectral range, as discussed later in this disclosure.

In a typical configuration of FIG. 4, with the separate outcoupler 31 and the composite gain crystal assembly 30 comprising an active laser medium and a nonlinear element, the length of shelf 25 may be further extended to about 5-7 mm. This would give the configuration of FIG. 4 a typical package length of about 12 mm. As for the transverse dimension, the 5.6 mm package diameter is still suitable for diode powers of up to 0.5 W, whereas a 9 mm package is more suitable for diode powers over 0.5 W—up to the maximum power permitted by heat removal considerations, as will be mentioned again below. In either case, the volume of the entire microlaser package may still be on the order of or less than about 1 cm³.

Advantageously, in constructing the micro laser of the foregoing example, both the outcoupler 31 and the microchip assembly 30 comprising elements 34 and 38 are picked and placed on extended shelf 25 using a precision alignment system. They can then be glued or soldered down to surface 21 of the shelf using, for example, a UV curable optical cement (or indium solder) in a manner similar to that used for the basic configuration of FIG. 3.

In one particular demonstration of the capabilities of a modified 5.6 mm package, it was found that, using a 0.5 W diode to pump a Nd:YVO₄/KTP composite according to methods of this disclosure, an intracavity converted green laser packaged in a 6 mm long package using a simple flat-flat fully monolithic resonator configuration, a (device constructed according to FIG. 3 is capable of producing tens of mW's of single-transverse-mode green output power with good alignment and high reliability characteristics. A discrete outcoupler may not, in fact, be required even for diode powers of 1 W or so suitable for the modified 9 mm microlaser package as was shown in demonstrations producing in excess of 100 mW green output. Thus the configuration of FIG. 4 including an external outcoupler may be required only when diode pump powers exceed 1 W, at least for the standatd frequency doubled CW Nd doped microchip laser.

Many variations of the basic TO package shown in FIGS. 3 and 4 are possible, and a few more are mentioned here. The diode used to pump the gain element of the microchip assembly may be either butt-coupled or direct-coupled, and the pump assembly may or may not include a short multimode fiber to symmetrize the astigmatic diode pump beam. The package may also be modified to house the microchip crystal assembly only, while the diode pump light is introduced through a fiber source. In addition, the diode may or may not include a fast-axis collimating (FAC) lens, or a slow axis collimating lens or both. Lensing of the diode is generally regarded as beneficial in equalizing divergence of the two dissimilar diode axes or else it may be used to collimate the diode output and reduce overall divergence thereby increasing pump coupling efficiency to the gain medium. Pre-lensed diodes may be sometimes provided as part of commercial diode lasers or else such a lens or lens composite may be added between the exit face of the diode and the crystal gain module as another customized variation of the basic packages of FIG. 3 or 4. As for the output characteristics of the diodes, these may be further selected from among commercially available semiconductor lasers, so that they may be adapted to pump a variety of media constructed from different gain and nonlinear material composites.

In different embodiments of the basic platform used to package the lasers, temperature control and/or stabilization of the miniature laser assemblies may be incorporated. For example, the wavelength of the diode laser may be controlled using Bragg gratings, thereby improving the overall stability characteristics of the device. Also, temperature control may be achieved by placing a thermistor or other miniature temperature sensing device, either externally or internal to the TO package. A miniature piezoelectric translator (PZT) may also be incorporated in the package for the purpose of enforcing a preferred laser output polarization or frequency tuning. In some applications where the laser output must be particularly noise-free, the entire package can be mounted on an external cooler such as a TEC to provide a constant operating temperature to the entire assembly. By temperature tuning the TEC to achieve SLM output, nearly noise-free lasers at the fundamental or harmonic wavelengths can be produced in this manner.

In more advanced versions, it may even be possible to contemplate employing a cryogenic cooling system by including, for example, cryogenic dewars, or cold fingers, or closed cycle Gifford-McMahon or Stirling coolers as part of an overall package. For certain materials, such as, for example, Yb:YAG, which operates on a quasi-three-level fundamental transition at room temperature, more efficient four-level operation is achieved at low temperatures, and cryogenic cooling techniques may be especially beneficial. Generally, any of the temperature control techniques known in the art of cooling lasers, including but not limited to the examples given above, may be incorporated with any of the aforementioned alternative TO packages (or even certain HHL packages), all of which fall within the scope of the invention.

To further aid in controlling the output of the laser, the package may also contain a photodiode for the purpose of providing feedback to an external electrical laser controller and/or controlling the temperature of the gain module, thereby providing constant power output with high amplitude stability over extended periods of time. Many such feed-back techniques are known in the art of constructing stabilized diode pumped lasers, any of which may be incorporated in the packages discussed above, subject to their compatibility with mass production methods. Such techniques may be used in place of or combined with the use of Bragg gratings for controlling the emission spectrum of the source diode.

We have determined that many of the optical, cooling and electrical elements needed to design and operate microlasers at various functional modalities can be constructed using the preferred methods of assembly and packaging. In all cases, the modified semiconductor laser packaging used to house the microlaser displays all the attributes desirable from devices that can be mass produced at low cost, offer the benefits of small size and weight, yet without sacrificing performance or reliability. In particular, the platform selected builds on the high degree of mechanical integrity, compatibility with heat dissipation techniques and built-in environmental shielding tools, characteristic of well tested long-lived diode packages. Yet, the packaging is flexible enough to allow many design extensions to thereby meet the requirements of a wide variety of applications, all from a common low cost, mass producible device platform

2. Crystal Fabrication.

In another key aspect of the invention described in this disclosure the cost of microchip crystal assembly and fabrication is addressed. In particular, we describe an innovative way to significantly reduce the size and the cost of manufacturing the crystal assemblies contained within the microlasers. These “high density” techniques, as they are collectively referred to, are described next.

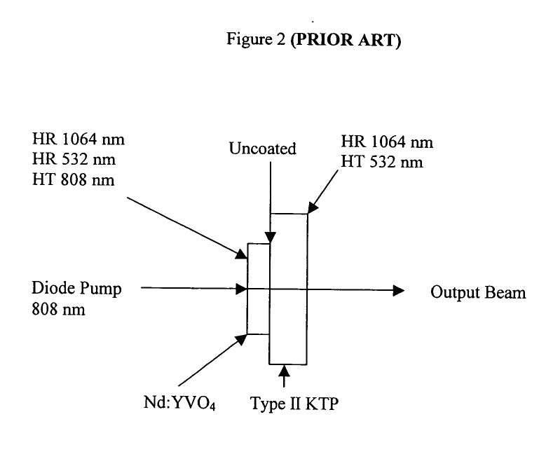

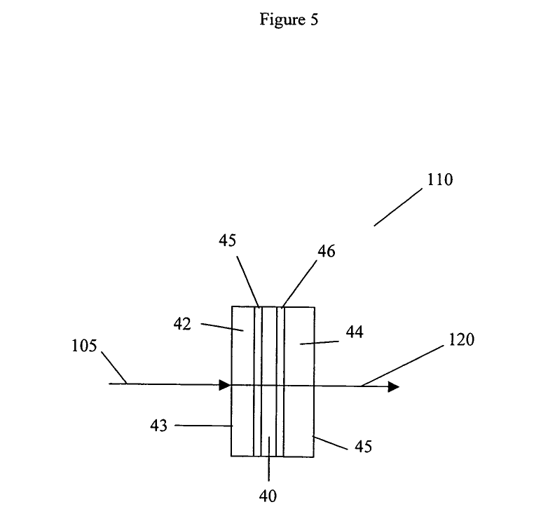

In one preferred embodiment, a crystal assembly 110 built according using high density techniques of the present invention is shown in FIG. 5. The assembly may comprise a gain material 42, and a nonlinear material 44. The nonlinear material may be cut to assure phase matching, for example, at the second harmonic of fundamental beam 105. In one preferred embodiment, using a Nd-doped gain material such as Nd:YVO₄ or Nd:YAG and a nonlinear crystal such as KTP or LBO, the output radiation 120 will be in the green region, typically at 532 nm. By contrast with the prior art configuration of FIG. 2, rather than contact bonding the internal surfaces of the two media, they may be glued together using an appropriate optical glue material 40. Bonding the surfaces together using inexpensive means is one of the elements essential to insuring that mass-production of green and other visible miniaturized lasers can be realized. The glue must fulfill a number of conditions such as robustness, resistance to out-gassing, and low absorption at the lasing and pump wavelengths. We have determined that various UV curable optical glues display the properties needed for this application, even at relatively high power levels.

Because of the index difference between the glue and the gain material on the one hand and the nonlinear material, on the other, there is however, a finite loss encountered at each glue-dielectric interface. These losses can be detrimental to the efficiency and intensity of the fundamental beam and especially to lasers where a SHG process is used intracavity. The loss can be particularly serious for low gain lasers, resulting in higher thresholds and lower slope efficiencies. To overcome this issue and obtain high performance comparable to those of contact-bonded laser assemblies, dielectric coatings 45 and 46 are preferably applied to the two internal faces of the assembly materials. The coatings must therefore be designed to establish strong optical contact between a dielectric crystal (such as Nd:YVO₄ or KTP) on one side, and the glue on the other side. Provided this can be accomplished, the resonator losses of the assembly are reduced to levels no higher than those to those typically seen with the more complicated contact-bonding assembly procedures. In one preferred example using Nd:YVO₄ as gain material 42 and KTP as nonlinear element 44, each have indices of about 2.03 and 1.77, respectively, (using the average of three crystalline axes for each). This compares with an index of refraction in the range of 1.45-1.6, typical of most glues. Without coatings, Fresnel losses due to index mismatch at each surface can be as high as 2.3%. Using coatings designed to be anti-reflective (AR) at each of the circulating wavelengths can reduce these losses to near zero. It is therefore important that the selected glue has properties allowing it to bond coated surfaces evenly and without damaging the coatings. It is noted here, that although the process of cementing AR coated surfaces is preferred due to cost and manufacturability considerations, optical contacting and diffusion bonding represent feasible approaches to producing the microchip gain crystal assemblies, as long as the techniques selected are economical and lend themselves to high density mass production processes.

To obtain lasing, the glued crystal assemblies must next be fabricated so that the two outside surfaces 43 and 45 of the assembly have the curvatures and/or the degree of parallelism required for the specific resonator design selected. In the simplest example, the two surfaces defining the resonator are chosen to be parallel to one another (a plane parallel resonator). The inner surfaces are typically polished flat to facilitate the bonding process. In one preferred approach, one of the dielectric plates comprising an optically active material (such as the gain or nonlinear crystal) is anchored in place during the fabrication process and a small amount of glue is placed in the center of the plate. The second dielectric plate is then placed on top of the first and the glue spreads out to form a thin uniform layer of glue. While exposed to light provided by a monochromatic source, the top plate is then “rocked” in a predetermined way to wash out the fringes formed by the light. When the fringes disappear, the resonator is considered to be interferometrically aligned. The glue layer is then exposed to ultraviolet (UV) light until it hardens. The fabrication process of the wafers may comprise first gluing the crystals together and then polishing the outside surfaces to form an interferometrically flat structure that is then coated. This method may be preferable where crystal wafers are thin and subject to bending from thin film induced stresses Alternatively, the plates may be polished first, then coated, then bonded using any of several preferred techniques, including cementing with UV curable glue, optical contacting or diffusion bonding, depending on the specifics of the crystal gain assembly and the required output characteristics of the laser. With any bonding technique it is important to insure that the entire wafer is usable. Therefore, it is essential to avoid any localized losses due to undesirable voids or bulges. To provide optimal contact quality across the full surfaces the wafers are preferably fabricated to be precisely flat and parallel across the full surface areas. The external surfaces of the bonded wafers may be polished to the requisite flatness tolerances before or after the bonding process.

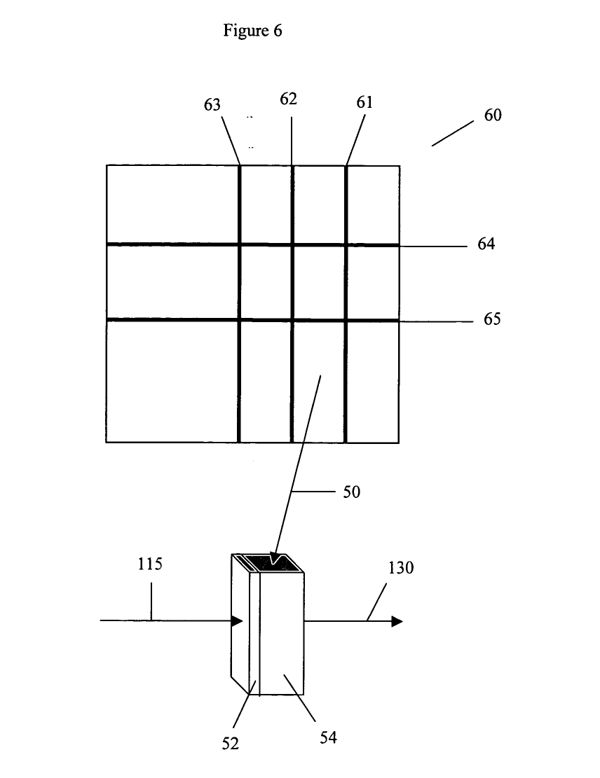

Once large crystal wafers are bonded together and the wafer is polished, the desired coating layers may be applied. A dicing saw may then be used as the next step in the process to cut numerous small laser resonator chips out of the composite wafer. Generally, optimal contact between the surfaces will maximize the number of crystal assemblies that can be produced from a single processed wafer. FIG. 6 shows an illustrative example of a large wafer assembly 60 which is diced along vertical lines marked 61, 62, 63 and horizontal lines 64, 65. In one example, the resulting microchip assembly 50 comprises a gain material 52 and nonlinear medium 54 glued together using the principles discussed for FIG. 5 above. Once cut, the crystal assembly is may be pumped by diode radiation 115, resulting in output beam 130, which in the foregoing example of a bonded Nd:YVO₄/KTP composite is at 532 μm. Note that this example is provided for illustrative purposes only. In practice, the number of assemblies, or “chips” that may be produced from a single bonded wafer is limited only by the size of available materials and the expense of tooling required to fabricate highly polished flat surfaces for specific media. In one example, a 6 mm×11 mm wafer of bonded Nd:YVO₄/KTP was produced then diced into nearly 40 gain crystal microchips.

A number of devices were demonstrated using the techniques discussed here. In one example, an optical glue was used to bond together plates of Nd:YVO₄ and KTP oriented for Type II phase-matching. The resulting devices were as small as 1 mm×1 mm and it is expected that further reductions in size are feasible using improved dicing technology. Using an 808 nm fiber pigtailed (0.22 NA, 100 μm core) laser diode butt-coupled to the microchip, sample devices produced 10-20 mW of green output at 532 nm with ˜200 mW of diode input pump power. These initial demonstrations of a glued microchip assembly used uncoated crystal surfaces next to the glue layer. Subsequent demonstrations of the technology have produced up to 80 mW using un-optimized dielectric coatings in contact with the adjacent glue layer. It is further noted that in the experimental demonstrations, an output beam that was both STM and SLM could be achieved and maintained by temperature tuning the microchip with a thermoelectric cooler (TEC). It is projected that by judicious application of optimized coatings, 100-200 mW of green output power will ultimately be produced from a single 1 W diode pump laser, approaching power levels demonstrated with the standard VLOC contact-bonded assemblies, but using the high density low cost fabrication techniques of the invention.

The foregoing used intracavity frequency conversion wherein the nonlinear crystal is placed internal to the resonator as primary example. As was already described earlier, this configuration is known to be well suited to low power and/or cw lasers because of the higher intensities of the fundamental beam prevailing inside the resonator. It bears mentioning however that although this configuration was used as a specific example carried throughout the disclosure, this was done primarily by way of illustration, and should not be construed as limiting the scope of the present invention. In particular, many of the techniques described herein can be applied to external conversion as well as other, more complicated frequency conversion techniques as will be described further below. In one particularly simple case, it should also be noted that the dicing technique can be applied to a single plate of diced crystalline material with no glue layer to thereby produce output at the fundamental wavelength (e.g., at 1064 nm for a Nd-doped material). In this case one surface of the wafer may be coated to be HR at the lasing wavelength (for example, at 1064 nm for Nd:YAG or Nd:YVO₄) and HT at the pump wavelength (typically near 808 nm or 880 nm for resonant pumping). The other surface will then serve as a partial reflector with the reflectivity optimized to provide efficient output. To further improve the efficiency the outcoupling surface may be also coated for HR at the diode wavelength to effect a second pass of the pump light. By packaging the microlaser laser according to the principles taught in FIG. 3, very compact, low cost devices can be built that are yet capable of delivering substantial power levels.

Following through the sequence of steps that comprise the technique disclosed herein, it is expected that very small laser “chips” (less than 1 mm in some cases) will be constructed from a single large wafer assembly, thereby reducing dramatically the cost per laser device. The high density techniques disclosed overcome the deficiency of the prior art wherein surfaces of individual crystals must be separately bonded for each assembly. This is because the internal surfaces in contact-bonded assemblies tend to de-bond during the dicing process. Also, unlike most of the prior art contact bonding techniques where much of the crystalline material is wasted, the methods of the present invention can be readily adapted to utilize the crystalline materials sparingly, with nearly all of the original wafer surface available to produce a large number of laser resonator assemblies. Furthermore, the glued microchips fabricated according to the procedures described herein readily lend themselves to usage in miniature packages that are fully compatible with the preferred packaging concepts described above. At the same time, the micro-assemblies display the same positive attributes as the contact-bonded assemblies available commercially. For example, they are can be constructed with the crystals' dimensions selected to facilitate STM and/or SLM operation. Furthermore, the processing techniques of the invention allow far greater flexibility in terms of operational parameters since many different materials lend themselves to be effectively glued together, whereas optical contacting requires separate optimization for each type of assembly. It is recognized however, as was pointed out above, that, in the future, crystal gain assemblies may also be fabricated using more sophisticated techniques of optical contacting or diffusion bonding, as long as the bonding process allows the manufacture of miniaturized low cost diode pumped lasers which can be produced at a large variety of wavelengths and output powers, simply through appropriate choices of coatings, crystals and resonator cavity optics—all using the same basic platforms and high density fabrication techniques. Thus, application of techniques such as contact bonding or diffusion bonding should not be construed as departing from the spirit of this invention, which generally relies on implementing economies of scale that were not feasible using prior art fabrication techniques and packaging approaches.

So far, the main focus in this disclosure was on preferred packaging, assembly and high density fabrication techniques suitable for constructing microlasers with mm dimensions or even smaller. As mentioned above, the techniques disclosed can be adapted to produce a large variety of laser types. Some of the materials and resonator design alternatives that can be implemented using the said preferred methods of mass production are discussed next.

3. Resonator Design.

Like mechanical packaging and gain module assembly and fabrication aspects, the resonator design for mass-producible micro lasers is inexorably tied to the overall cost of manufacturing the devices. In particular, the resonator design must be simple, yet capable of reliably producing the requisite performance with good optical stability, low noise and acceptable lifetime characteristics. In some cases, the microlaser is expected to produce STM and SLM output. In other, less demanding cases the beam does not have to be STM but can be a lower-order mode while in others STM is required but not SLM.

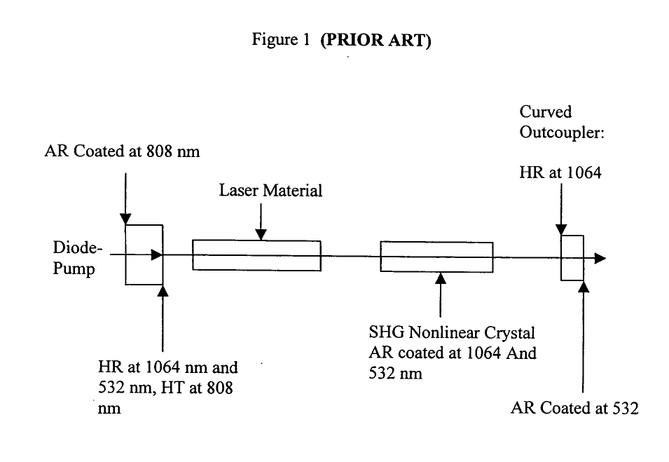

One resonator structure of particular interest concerns the intra-cavity frequency doubled cavity. Generally, the cavity design in this case follows principles well known in the art of constructing diode end pumped intracavity doubled lasers deriving from the generic configuration of FIG. 1, but modified to fit the miniaturized package and high density manufacturing techniques that are the subject of the present invention. As is common practice, the second harmonic (SH) or nonlinear crystal is advantageously placed between the lasing material and the outcoupler, which may comprise a coating placed on the SH material itself or a separate element. Examples of commonly used nonlinear materials are KTP, LBO, BBO, KNbO₃, LiNbO₃ and periodically poled materials such as PPLN and PPKTP, The nonlinear crystal end faces are usually AR coated at both the fundamental and at the second harmonic wavelengths, a design feature already described in connection with the microchip assembly of FIG. 5. Use of appropriate coatings is important for obtaining good second harmonic generation (SHG) efficiency by minimizing losses due to Fresnel reflections the fundamental wavelength at the end faces of the nonlinear crystal. The nonlinear crystal orientation and crystal cut are selected to insure that phase-matching occurs between the fundamental and SH wavelengths, following standard procedures known in the art of optimizing frequency conversion efficiency. The nonlinear crystal may be cut for Type I or Type II phase-matching, or it may comprise a periodically-poled crystals such as PPLN or PPKTP. The gain material may comprise any commonly available solid state laser medium, including Nd, Yb, Er and Tm doped crystal hosts. Based on current state of the art, the simplest miniaturized lasers suitable for producing SH radiation in the visible are based on materials such as Nd:YAG and Nd:YVO₄. Nd:YVO₄ is especially attractive because of its high gain and absorption properties as well as ready manufacturability. In particular, excellent performance has been demonstrated using Nd:YVO₄ in conjunction with nonlinear materials such as KTP and LBO. A microchip gain assembly comprising Nd:YVO₄ and KTP has already been successfully demonstrated using the preferred fabrication techniques of the invention and is therefore used to illustrate some of the foregoing resonator examples discussed below. It is understood however that many other gain and nonlinear material combinations fall within the scope of the invention, provided they are commercially available in the requisite sizes.

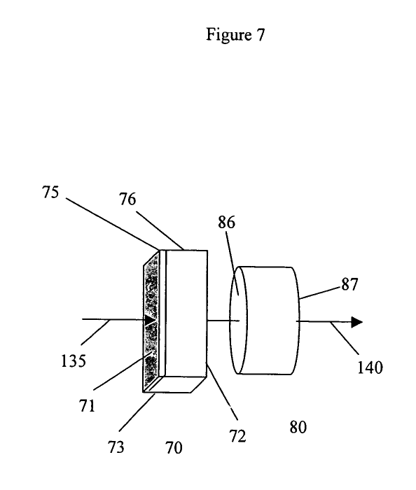

The simplest and easiest resonators to produce at low cost are flat/flat resonators because it is relatively straight forward to optically finish two surfaces to be parallel to one another and the crystal assemblies are therefore amenable to the fabrication cost savings associated with flat crystalline elements. It is, however, well known in the art of designing diode end-pumped lasers, that some curvature may need to be introduced into the resonator to assure stable operation, especially at higher output powers. Thus, a flat/flat resonator design typically relies upon the induced thermal focusing or gain-guiding, or in some instances both to supply the requisite curvature. The all-planar cavity design is, however, power limited. For example, in the case of a bonded Nd:YVO₄/KTP crystal assembly glued to a shelf—as was described in connection with FIGS. 3 and 4 above, it was found through experimentation, that when the 532 nm output power exceeds about 30 mW, alignment of the crystal assembly becomes overly sensitive and difficult to maintain. However, if proper heat sinking could be provided for the crystal assembly, for example by means of wrapping the assembly in heat conducting metallic foils, it was found that the all-planar cavity is capable of producing greater than 150 mW of green output power. It is noted here that similar resonator stability limitations also applied to commercially available contact-bonded crystal assemblies and are related to well known stability considerations for flat resonators, rather than any aspects unique to the type of bonding used. Thus, for higher powers (e.g., in excess of about 100 mW in the infrared and about 30 mW in the green without applying special heat sinking means) an alternative resonator design using, preferably, a flat/curved mirror configuration (the standard hemispherical resonator design, for example) is sufficient to enforce stability and thereby maintain alignment. Accordingly, an example of a preferred embodiment of a microlaser design using a flat/curved resonator is shown in FIG. 7. This example depicts an intracavity frequency doubled laser using a crystal assembly 70 comprising a gain medium 75 and a frequency doubling crystal 76 glued together according to the principles outlined earlier and producing an output beam at the SH wavelengths. In a manner generally similar to that shown previously for FIG. 5, the microchip assembly is constructed with the interface 73 between the gain material 75 (such as Nd:YVO₄) and the nonlinear crystal plate 76 (made of e.g., KTP) filled by a layer of optical cement (not shown in FIG. 7) and the faces in contact with the cement layer are preferably dielectrically coated with suitable AR coatings to eliminate reflective losses. A coating that is high reflecting (HR) at the fundamental and SH wavelengths but is transparent to the wavelength of diode pump beam 135 is applied to the flat surface 71 of assembly 70, similar again to the embodiment of FIG. 5. However, a discrete curved outcoupler 80, coated to extract the second harmonic radiation, is now added to form the cavity. The output face 72 of the nonlinear material is then AR coated at both the fundamental and SH wavelengths (instead of the HR coating shown previously in FIG. 5). Preferably, the outcoupler element 80 is placed close to or in contact with the nonlinear crystal output face 72 to maintain the small dimensions of the laser. The outcoupler may have a finite curvature on its left surface 86 (facing the nonlinear element), in which case this surface may be preferably coated so it is HR at 1064 nm and HT at 532 nm. The particular magnitude of the curvature is chosen to provide stability to the resonator, following standard optical design methods know in the art. The output surface 87 of the outcoupler 80 may be coated to be AR at the SH, following the standard procedure for an intracavity doubled laser. Implementing a flat/curved cavity design for the case of a microchip assembly consisting of YVO₄ gain material and KTP doubler, it was found that this configuration provides stability and maintains STM output for 532 nm output powers well above 200 mW, allowing the microchip resonator to produce scaled-up green output power levels with good beam-quality. Furthermore, while the flat/curved embodiment may be somewhat more expensive than the flat/flat microchips previously discussed due to added materials and fabrication costs, it maintains the advantages of compactness, easy alignment and high density manufacturing techniques as compared to prior art techniques.

It is also noted that in a variation of the flat/curved embodiment of FIG. 7, the curvature may be put on the output or right face 87 of the outcoupler 80, leaving the left inside surface, 86 flat. Such a configuration would allow the outcoupler 80 to be directly glued to the SH crystal AR coated surface 72 forming a three plate sandwich structure, using, e.g., the same optical cement employed in the previously discussed examples. Inner surface 86 of the outcoupler would then be preferably dielectric coated to minimize reflective losses, whereas the outer curved surface 87 may be coated for HR and HT at the fundamental and SH wavelengths, respectively.

There are many other variations on the basic intracavity doubled resonator of FIG. 7, as most of the possible prior art approaches applicable to bulk lasers of the kind shown in FIG. 1 can be implemented in a miniaturized form using the packaging and high density production techniques that are the subject of the present invention. As one example, the backward traveling green light in the resonator can be collected by placing HR coating appropriate to the SH wavelength on the left surface 73 of the nonlinear crystal 72 instead of the AR coating described earlier. This avoids having to pass the SH beam through the laser crystal 75, though at a cost of some added complexity to the cavity design and more stringent requirements on the adhesive used to affix the gain crystal to the nonlinear material. In still another embodiment, more than one wavelength can be provided simultaneously from a single micro resonator. For example, using appropriate coatings, a crystal assembly such as that shown in FIG. 5 can be designed that will simultaneously produce output at 1064 nm and 532 nm. These and other variations on the basic intracavity frequency converted design of FIG. 1 that are known to one skilled in the art all fall within the scope of the present invention.

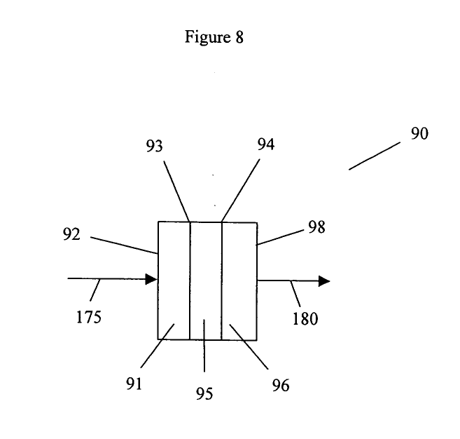

Additional nonlinear crystals may also be inserted into the cavity in order to convert the second fundamental wavelength into higher harmonics, for example, in the UV, in which case, the microchip assembly components and the associated coatings have to be modified appropriately. Particularly, fabrication of gain assemblies using the techniques of gluing and processing larger wafers followed by dicing into miniaturized assemblies can be extended to crystal assemblies with multiple rather than just the two wafers shown earlier. FIG. 8 shows an example of a crystal assembly design that can be used to produce third or fourth harmonic light from a fundamental transition such as the 1064 nm transition in Nd:YAG or Nd:YVO₄. The assembly 90 in this embodiment may consist of a gain material 91, a first nonlinear material 95 and a second nonlinear material 96. The first nonlinear material is typically a crystal cut for SHG and the second nonlinear material may be cut for third harmonic or fourth harmonic generation. In one example, the gain material is Nd:YVO₄, the SH crystal is KTP and the second nonlinear crystal may be LBO or BBO. The cut of the crystals and the coatings determine whether third harmonic at 355 nm or fourth harmonic at 266 nm are generated. The left outer surface 92 of the assembly is typically coated to be HR at the fundamental and SH wavelengths and HT at the pump wavelength so as to allow pump radiation 175 to excite the active ions in gain medium 91. The coating on the outside right face 98 of the assembly is preferably selected to be HR at the fundamental and HT at the wavelength of output beam 180. Since surface 98 of the second nonlinear crystal serves as an output coupler, it may be polished flat or curved, depending on conditions required to maintain cavity stability for given level of circulating power. The resonator is then formed between this outcoupler surface and the HR coated left surface 92 of the gain material 91. For third harmonic generation (THG), the coating on outside right surface 98 may be further selected to provide high reflection also at the second harmonic so as to allow another pass through the third harmonic crystal 96, which then combines again with the resonating fundamental in a sum frequency mixing (SFM) process thereby doubling the overall UV output. For fourth harmonic generation (FHG) on the other hand, the surface 98 may instead be coated for either HT or HR at the SH wavelength, depending on the required power and propensity to damage of the optical components at the fourth harmonic wavelength. The interface 93 between the gain material and the first nonlinear crystal and interface 94 between the two nonlinear crystals are each cemented using appropriate optical glue as was described in connection with FIG. 5. The interface 93 is preferably formed between with each of the two cemented surfaces AR coated at both the fundamental and the SH wavelengths as was also described earlier. Interface 94 comprises two similarly AR coated surfaces for the fundamental and SH that are adhered together using an appropriate optical cement. To prevent any residual third or fourth harmonic beam from traveling back through the SH crystal 95 and the gain material 91, another coating layer on the inside surface of second nonlinear crystal 96 may be deposited so that it is HR in the UV—with peak reflection at either the third or fourth harmonic wavelength, depending on the desired output.

Still other crystal assemblies may be fabricated to provide multiple wavelengths using Stokes shifting in solid-state Raman converters such as calcium tungstate (CaWO₄). A simple example would be to construct an microchip assembly by gluing or bonding a solid-state Raman material to a Nd-doped crystal, with the facing surfaces deposited with appropriate dielectric coatings. Raman shifted output from a Nd-doped crystal such as Nd:YVO₄ emitting at 1064 nm include discrete Stokes shifted lines between 1.15 out to longer than 1.5 micron. In the case of calcium tungstate, the first shifted Stokes line is at about 1.18 mm. This line can be frequency doubled (externally or internally) to give radiation in the yellow near 589 nm, corresponding to the important sodium line.

The inventive techniques used to produce micro lasers as described so far may also be adapted to provide resonator configurations operating on any number of alternative laser transitions, depending on the application needs. Table 1 lists some of the transitions utilized in commonly used Nd-doped laser materials. Clearly the SHG, THG and FHG processes described above can be applied to any laser transition as long as a suitable nonlinear crystal can be identified that will phase match to provide the requisite harmonic output. Alternatively, embodiments where two laser transitions are combined intracavity using a nonlinear crystal cut to phase match for SFM, thereby further increasing the range of wavelengths that may be produced with the high density microchip fabrication and miniature laser packaging principles described in the disclosure. In one particular example, not shown explicitly in Table 1, one could, for example, use SFG of the 1318.7 nm and 946 nm transitions in Nd:YAG to produce yellow laser radiation at 550.84 nm. This spectral range may be especially useful for biomedical and bioinstrumentation applications.

TABLE 1
Fundamental and Second Harmonic Wavelengths for
Various Laser Crystals
Laser Transitions Assumed Operating Near 300° K

| | Fundamental | |
|---|---|---|
| Material/ | Wavelength | SHG Wavelength |
| Transition | (nm) | (nm) |
| Nd: YAG | | |
| ⁴F_{3/2}-⁴I_{13/2} | 1318.70 | 659.35 |
| ⁴F_{3/2}-⁴I_{11/2} | 1064.20 | 532.10 |
| ⁴F_{3/2}-⁴I_{9/2} | 946.00 | 473.00 |
| Nd: YVO₄ | | |
| ⁴F_{3/2}-⁴I_{13/2} | 1341.92 | 670.96 |
| ⁴F_{3/2}-⁴I_{11/2} | 1064.28 | 532.14 |
| ⁴F_{3/2}-⁴I_{9/2} | 915.25 | 457.63 |
| Nd: YALO | | |
| ⁴F_{3/2}-⁴I_{13/2} | 1341.40 | 670.70 |
| ⁴F_{3/2}-⁴I_{11/2} | 1079.50 | 539.75 |
| ⁴F_{3/2}-⁴I_{9/2} | 870.00 | 435.00 |
| Nd: YLF | | |
| ⁴F_{3/2}-⁴I_{13/2} | 1313.00 | 656.50 |
| ⁴F_{3/2}-⁴I_{11/2} | 1053.00 | 526.50 |
| ⁴F_{3/2}-⁴I_{11/2} | 1047.00 | 523.50 |
| ⁴F_{3/2}-⁴I_{9/2} | 908.27 | 454.13 |
| ⁴F_{3/2}-⁴I_{9/2} | 903.50 | 451.75 |
| Yb: YAG | | |
| ²F_{5/2}-²F_{7/2} | 1029.30 | 514.65 |

Not shown in Table 1 are many other potential active ions and laser host combinations that may be amenable to the microchip resonator fabrication and packaging techniques. Such combinations may include alternative rare earth ions such as Er, Tm and Yb doped into host crystals that include garnets, such as YAG, vanadates and fluorides such as YLF. Essentially any ion/host crystal combination may be utilized as long as the crystals are manufacturable in sufficient sizes and good enough quality to be amenable to the high density fabrication processes of interest here.

It is noted that solid state lasers that are the subject of this disclosure may be operated in many temporal formats, including continuous-wave (CW), Q-Switched (QS), Long-Pulse (LP), and Mode-Locked (ML). Whereas most examples shown this far including the intracavity frequency converted laser embodiment and the associated microchip assemblies of FIGS. 5 to 8 are indicated as operating in a CW mode, the general principles of the invention are also valid for the corresponding pulsed cases. In analogy with methods well known in the art, a variety of means can be used to change the temporal format of the output from the CW format.

In the simplest approach, the laser diode source can, for example, be modulated, that is—turned on and off at some desired rate so as to produce laser output that is rising and falling in a manner generally proportional to the laser diode power. For 100% laser diode modulation, turning the laser diode pump off and on at a prescribed repetition rate produces long-pulse or free-running output at the same repetition rate. As frequency conversion efficiencies are not expected to be markedly affected in this case, the harmonic output produced in any of the intracavity configurations described above will therefore be modulated but with the overall average power output the same as that obtained for the corresponding CW case.

In another class of alternative embodiments, a Q-switch—either an active modulator or a passive saturable absorber—may be inserted in the cavity to provide Q-switched (QS) operation with pulse durations in the nanosecond range or even below, depending on the laser material, repetition rate and overall cavity length. In particular, there are prior art teachings that demonstrate the viability of adding a Q-switch to the basic intracavity doubled resonator of FIG. 1 to thereby provide short pulse operation in the few nanoseconds or even the sub-nanosecond range. The Q-switch may be an active modulator, such as an AO or EO Q-Switch or it may comprise a passive Q-switch, such as Cr⁴⁺:YAG. Examples of a prior art techniques using Q-switching in a microlaser include, among others, U.S. Pat. No. 5,703,890 where an active Q-switching technique was described and U.S. Pat. Nos. 6,023,479 and 5,488,619 where passive QS microcavities were taught using passive Q-switching and/or mode locking means. These and other similar techniques amenable to the packaging and high density fabrication techniques that are the subject of the invention are all incorporated by reference herein. Some examples of Q-switched gain crystal assemblies that could be constructed and packaged with the techniques of the invention are described next.

In general, whereas CW intracavity conversion efficiencies can exceed 30% for simple laser designs, conversion efficiencies exhibited by pulsed lasers may exceed 50% due to higher intracavity intensities. Consequently, the intracavity converted output from a QS laser embodiment may have average power that is higher than the corresponding CW case—for the same input pump power. In addition, the higher peak powers attainable through use of a QS allow the laser to address the needs of the large number of applications where short pulse durations are a prerequisite. It is therefore of interest to construct pulsed versions of the miniaturized resonators discussed earlier using high density techniques and compact, low cost packaging approaches disclosed in this invention.

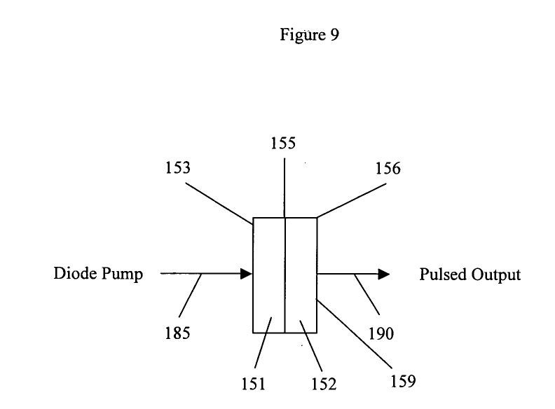

In one alternative embodiment a miniature devices can be Q-switched using for example a saturable absorber. The saturable absorber can be doped into the lasing crystal itself (self-Q-switching) or into a separate crystal. In FIG. 9 we show an example of a preferred embodiment of a microchip design used to produce Q-switched pulses. In this example, a gain crystal (such as Nd:YVO₄) is pumped by radiation 185 from a diode source that may be CW or pulsed (modulated) and the output radiation 190 is pulsed. The left face 153 of the crystal is, again, HR coated at 1064 nm and HT at 808 nm. The crystal 152 to the right can comprise a commonly used passive Q-switching material such as Cr⁴⁺:YAG, that has a partially reflecting coating at 1064 nm applied to its right face 156. The interface 155 between the two crystals may again comprise an optical glue and the surfaces in contact with the glue are dielectric-coated to minimize reflective losses in the same manner as was done for the CW assemblies described above (see for example, FIG. 5). According to the high density procedures of the present invention, the completed glued microchip assembly, including the saturable absorber, is preferably produced using large starting wafers that are glued together using interferometric control means to assure optimum alignment, followed by and dicing into a large number of miniature gain chip modules. In this manner the economies of scale inherent in the present invention are extended to pulsed resonator assemblies. In particular, using Nd-doped material such as vanadate or YAG, micro-joule level pulse energies (typically 3-10 μJ) at 10's of kHz repetition rates can be produced at or near 1064 nm from miniaturized low cost devices—preferably with a bill of materials under a hundred to a few hundred dollars—an achievement not duplicated by any of the techniques known in the art, including those utilizing optically bonded devices. In one example, a micro-joule level, over 100 mW could be produced using a pulsed 0.5-1 W laser diode pump source with a pump duration comparable to or shorter than the fluorescence decay time for a Nd:YVO₄ crystal (typically ˜100 μsec). Such pulsed diode lasers are readily available from several commercial vendors. Optical damage to the glue layer has been shown not to be an issue for this level of operation of the microlasers. Specifically, in experiments conducted to date, intensities above 250 MW/cm² have been sustained for over 10⁹ shots with no apparent degradation to the glue layer or AR coatings.

Still greater economies can be realized for these pulsed resonator assemblies. In one alternative example, it may be possible to take advantage of the fact in some materials such as Nd:YAG for example, the Cr⁴⁺ ion can be co-doped with the active Nd ion. This will allow the Q-switched laser to be made into a single plate that can be diced and fabricated into smaller microchip assemblies, lowering further the overall cost of fabrication.

In other versions of the basic device of FIG. 9 alternative crystals and Q-switches may be selected to provide different output wavelengths. One such alternative version would comprise an assembly designed for eye-safe operation consisting of a gain material made of Yb,Er:Glass, operating at 1540 nm and a passive Q-switch made of Co²⁺: Spinel or some other material appropriate 1 to this wavelength. In this case, the Yb absorption band is pumped by a diode operating near 940 nm followed by energy transfer to the Er ion which lases at 1540 nm. Because the crystal thicknesses can be minimized in this case, this type of a pulsed eye safe micro-laser is highly amenable to mass production by dicing large glued wafers into numerous small assemblies.

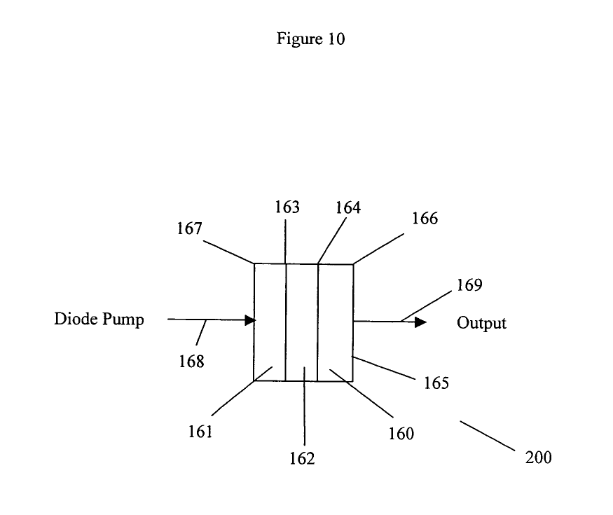

The methods of producing QS operation may be extended to utilize more complicated microchips operating at other wavelengths and alternative operating modes, as long as appropriately optimized resonator constructions are implemented to realize desired operation. In one embodiment of a frequency converted Q-Switched laser resonator providing pulsed SH radiation, the gain/saturable absorber microchip assembly of FIG. 9 is extended to a three plate composite 200 as shown in FIG. 10. Here, the gain crystal 161 is cemented to a saturable absorber Q-switch 163 which is then glued to a nonlinear crystal 165 such as KTP or LBO. The coatings on the left side 162 are selected to allow high reflection of the fundamental and the harmonic and high transmission of the diode pump radiation 168. The coatings on the right surface of the assembly 1167 may be selected to optimize the power of the harmonic radiation 169. The interface 163 between the gain material and the Q-switch comprises the cemented AR-coated surfaces of the optical elements. The cemented surfaces comprising interface 164 between the Q-switch and the nonlinear element may be deposited with multi-layer coatings, the design of which may be unique to each assembly and resonator design. For an intracavity frequency doubling embodiment the surfaces may be dielectrically coated for AR for both the fundamental and the SH. In this case, the right hand side 167 of the assembly, which may be flat or curved is advantageously coated for HR at the fundamental and HT at the SH, in a manner similar to the CW gain module of FIG. 5. Alternatively, in such a Q-switched resonator, extra-cavity frequency conversion is also feasible with high efficiency, and may be preferred in certain instances. An extra-cavity arrangement may be implemented through the simple means of choosing different coatings on the different surfaces. For example, interface 165 may be coated for PR at the fundamental and HR at the SH, while the output surface 167 is coated for HT at the SH as for the intracavity case. Numerous other options are feasible with this basic design, depending on the required power levels, availability of coatings, and desired wavelengths. At higher power levels, considerations of damage to both coatings and cement may dictate preferred resonator design.

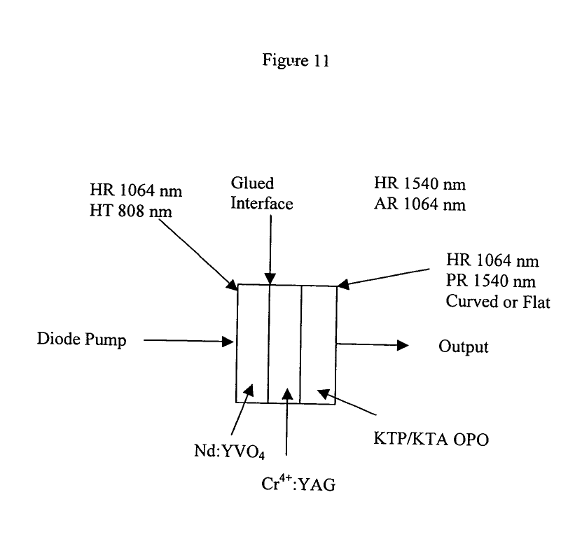

Several interesting alternative embodiment of the basic QS assembly of FIG. 10 are feasible. In one example shown in FIG. 11, an eye-safe laser operating near 1540 nm may be produced using an optical parametric oscillator (OPO) device consisting of appropriately coated KTP or KTA crystal for the nonlinear element 165 of FIG. 10. In this case, the three layer microchip laser assembly may comprise a Nd:YVO₄ gain crystal glued to a Cr⁴⁺:YAG Q-switch, which is, in turn, glued to a KTP or KTA nonlinear crystal phase-matched to the 1064 nm fundamental transition in Nd:YVO₄. The right face corresponding to surface 167 in FIG. 10 of the KTP/KTA crystal may be curved to provide resonator stability and allow operation in STM and is coated for HR at 1064 nm and PR at 1540 nm. The interface 164 for this embodiment would be preferably coated for HR at 1540 nm and AR at 1064 nm, following standard design for an OPO. The other interface—corresponding to numeral 163 in FIG. 10, has both surfaces coated simply for AR at the fundamental. The output comprises the desired 1540 nm output which is pulsed at repetition rates on the order of 10's of kHz. Expected pulse durations of this microchip laser assembly are in the range of a few nanoseconds.

It is noted that this type of a laser microchip tends to be significantly longer than the devices shown previously because the nonlinear coefficient for 1.54 μm generation is small and as much as 1-2 cm of the OPO crystal length may be required to produce good efficiency. Still, existing TO or HHL packages may be modified or custom re-designed to realize this eye-safe laser. In other regards the procedures to be followed are similar to the ones described in connection with the SHG and THG devices, maintaining overall economy in the fabrication process, with the crystals consisting of larger wafers all glued together and the desired interface coating properties designed to be in contact with an appropriate optical glue. Subsequent dicing into smaller microchips provides the economies of scale as in the case of the other, simpler assemblies.

For higher power versions of the pulsed micro-lasers, thin plates of electro-optically active material such as Lithium Tantalate may be used to actively Q-switch the resonator. In particular, a Q-switch element may be inserted in the higher power resonator version of FIG. 7 to allow power scaling of the fundamental or SH output. Miniature low-cost pulsed resonators can therefore be built even for high peak powers using techniques disclosed in the invention. All such extensions of the basic resonator designs fall within the scope of the present invention, provided they are amenable to the high density fabrication techniques and low cost mass producible packages that are of interest here.

Note that the foregoing descriptions of preferred and alternate embodiments of the invention have been presented for purposes of illustration and description and are not intended to be exhaustive or limit the invention to the precise forms disclosed. Thus, there are numerous specific implementations of a microchip laser technology that are capable of low cost mass-production using the techniques of gluing coated crystal wafers together followed by dicing into numerous microchips. Similarly, there are variations of the basic optical resonators and output wavelengths used to illustrate the packaging concepts. Whereas the invention has been described and illustrated with reference to certain particular embodiments thereof, it should be apparent to practitioner in the art that many more modifications and variations of the basic ideas are possible and that the various adaptations, changes, modifications, substitutions, deletions, or additions of procedures and protocols may be made without departing from the spirit and scope of the invention. For example, mere substitution of a different resonator, operating mode, laser materials, Q-switches or method of Q-switching, nonlinear crystals, coatings or combinations of coatings should not be construed as departing from the spirit of the invention as described herein. Nor should any method of cementing the crystals together (using for example alternative glues, cementing techniques and bonding procedures than the ones specifically mentioned) be considered excluded from the scope of the invention. Expected variations or differences in the results are contemplated in accordance with the objects and practices of the present invention. Thus, It is intended that the scope of the invention be defined by the following claims and their equivalents.

1. A miniaturized solid state laser package comprising,
a gain crystal assembly, including at least one active laser medium, pumped by a diode laser, having a pumping wavelength, whereupon the laser medium emits radiation at a lasing wavelength,
the gain crystal assembly disposed within a resonator cavity defined by two opposing mirrors, wherein at least one of the mirrors consists of a coating configured for high reflection at the lasing wavelength and high transmission at the pumping wavelength and placed directly on the surface of the gain crystal assembly proximate to the diode laser and the second mirror is an outcoupler defining the exit face of the resonator; and
wherein the resonator cavity is mounted on a shelf configured as an extension of the mounting platform supporting the emitting diode laser in a standard TO semiconductor package.

2. The solid state laser package of claim 1 wherein the TO package is selected from a group consisting of 5.6 mm, 9 mm, TO-3 and TO-5.

3. The solid state laser package of claim 1 further including means for stabilizing the power output of the resonator.

4. The solid state package of claim 3 wherein said power stabilization is carried out using a feedback control loop including a photodiode for sensing the power output.

5. The solid state package of claim 3 wherein said power stabilization means includes methods for controlling and adjusting the temperature of the gain crystal assembly.

6. The solid state laser package of claim 1 where the gain crystal assembly is enclosed in a heat sink.

7. The solid state laser package of claim 1 further including means for stabilizing the output wavelength of the diode laser.

8. The solid state laser of claim 1 wherein the TO package is mounted on an external cooler.

9. The miniature laser package of claim 1 wherein the gain crystal assembly comprises a composite of two elements at least one of which is the active laser material.

10. The laser package of claim 1 wherein the second element of the gain crystal assembly is a nonlinear medium.

11. The laser package of claim 1 wherein the active laser element comprises a rare earth element doped in a host.

12. The solid state laser package of claim 11 wherein the rare earth element is Nd.

13. The laser package of claim 10 wherein the nonlinear element is configured for generating the second harmonic of the laser radiation.

14. The laser package of claim 10 wherein the nonlinear element is configured and coated for parametric generation of radiation.

15. The laser package of claim 9 wherein the composite gain assembly comprises the combination of Nd:YVO₄ gain crystal and a KTP nonlinear material.

16. The laser package of claim 10 wherein the nonlinear material is selected from the among the group consisting of KTP, LBO or KNbO₃.

17. The solid state laser package of claim 1 wherein the gain crystal assembly comprises a composite of the active laser material and two nonlinear crystals.

18. The solid state laser package of claim 17 wherein the first nonlinear element is configured for second harmonic generation and the second harmonic crystal is configured for generating a third or fourth harmonic of the laser radiation.

19. The solid state laser package of claim 1 wherein the composite gain crystal comprises two active laser materials.

20. The solid state laser package of claim 1 wherein the gain crystal assembly is affixed to the shelf using a glue.

21. The solid state laser package of claim 1 wherein the gain crystal assembly is affixed to the shelf using solder.

22. The laser package of claim 1 wherein the outcoupler mirror is deposited directly on the surface of gain crystal assembly distal to the pumping diode.

23. The laser package of claim 1 wherein the outcoupler mirror comprises a discrete optical element spaced apart from the gain crystal assembly and in alignment with the other resonator elements.

24. The laser package of claim 23 wherein the outcoupler has a curved surface.

25. The laser package of claim 1 wherein the resonator cavity is configured as a flat-flat stable configuration.

26. The laser package of claim 1 wherein the resonator cavity further includes Q-switch means adapted to provide pulsed radiation.

27. The laser package of claim 26 wherein said Q-switch comprises a saturable absorber.

28. The laser package of claim 26 wherein said Q-switch comprises an active modulator.

29. The solid state laser package of claim 1 wherein the gain crystal assembly comprises at least two elements.

30. The solid state laser package of claim 29 wherein the two elements of the gain crystal assembly comprise dielectrically coated plates.

31. The solid state laser package of claim 29 wherein the elements are cemented using optical glue.

32. The solid state laser package of claim 29 wherein the elements of the crystal assembly are bonded using optical contacting

33. The solid state laser package of claim 29 wherein the elements of the crystal gain assembly are bonded using the technique of diffusion bonding.

34. The solid state laser package of claim 29 wherein the elements of the gain crystal assembly are joined using methods that reduce losses due to Fresnel reflections to less than 1% per pass.

35. The solid state laser package of the claim 1 wherein the gain crystal assembly is fabricated using high density techniques.

36. The solid state laser package of claim 35 wherein the gain crystal assembly is fabricated by dicing polished and coated crystal wafers into a plurality of miniature crystal gain modules.

37. The solid state laser package of claim 1 wherein the process of manufacturing the gain crystal assembly is carried out through the steps of first joining wafers of the separate elements using low loss bonding techniques, followed by application of coatings after which the composite wafers are diced into a plurality of miniature crystal gain assemblies.

38. The solid state laser package of claim 1 wherein the process of manufacturing the gain crystal assembly is carried out through the steps of first cementing wafers of the separate elements together into a composite wafer using glue, followed by polishing the composite wafer interferometrically flat followed by application of coatings after which the composite wafers are diced into a plurality of miniature crystal gain assemblies.

39. The solid state laser package of claim 1 wherein the power output from the pump diode is at least 250 mW.

40. The solid state laser package of claim 36 wherein the power output is at least 100 mW in a fundamental laser radiation.

41. The solid state laser package of claim 14 wherein the green power output is at least 1 mW.

42. The solid state laser package of claim 1 wherein the resonator cavity is adapted to provide output in a single longitudinal mode.

43. The solid state laser package of claim 1 wherein the resonator cavity is adapted to provide output in a single Transverse mode.

44. The solid state laser of claim 1 wherein the volume of the entire package is less than 1 cm³

45. A miniaturized solid state laser package comprising,
a gain crystal assembly, including at least one active laser medium, pumped by a diode laser, having a pumping wavelength, whereupon the laser medium emits radiation at a lasing wavelength;
the gain crystal assembly disposed within a resonator cavity defined by two opposing mirrors, wherein one of the mirrors is coated for high reflection at the lasing wavelength and high transmission at the pumping wavelength and the second mirror is an outcoupler defining the exit face of the resonator; and wherein the solid state laser package has a volume that is less than about 1 cm³.

46. The solid state laser package of claim 45 wherein the package is a semiconductor laser TO package adapted and configured to hold the gain crystal assembly.

47. The solid state package of claim 45 including means for controlling and adjusting the temperature of the gain crystal assembly.

48. The solid state package of claim 47 wherein the means for controlling and adjusting the temperature comprise a TEC.

49. The solid state laser package of claim 45 where the gain crystal assembly is enclosed in a heat sink.

50. The miniature laser package of claim 45 wherein the gain crystal assembly comprises a composite of two elements at least one of which is the active laser material

51. The laser package of claim 45 wherein the second element of the gain crystal assembly is a nonlinear medium.

52. The laser package of claim 45 wherein the active laser element comprises a Nd doped laser host.

53. The laser package of claim 51 wherein the nonlinear element is configured for generating the second harmonic of the laser radiation.

54. The laser package of claim 51 wherein the composite gain assembly comprises the combination of Nd:YVO₄ gain crystal and a KTP nonlinear material.

55. The laser package of claim 51 wherein the nonlinear material is selected from the among the group consisting of KTP, LBO or KNbO₃.

56. The solid state laser package of claim 45 wherein the gain crystal assembly comprises a composite of the active laser material and two nonlinear crystals.

57. The solid state laser package of claim 45 wherein the composite gain crystal comprises two active laser materials.

58. The laser package of claim 45 wherein the outcoupler mirror is deposited directly on the surface of gain crystal assembly distal to the pumping diode.

59. The laser package of claim 45 wherein the outcoupler mirror comprises a discrete optical element spaced apart from and in alignment with the gain crystal assembly.

60. The laser package of claim 59 wherein the outcoupler has a curved surface.

61. The laser package of claim 45 wherein the resonator cavity is configured as a flat-flat stable configuration.

62. The laser package of claim 45 wherein the resonator cavity further includes Q-switch means adapted to provide pulsed radiation.

63. The laser package of claim 62 wherein said Q-switch comprises a saturable absorber.

64. The laser package of claim 62 wherein said Q-switch comprises an active modulator.

65. The solid state laser package of claim 45 wherein the gain crystal assembly comprises at least two elements.

66. The solid state laser package of claim 65 wherein the elements of the gain crystal assembly are joined using low loss methods that reduce losses due to Fresnel reflections to less than 1% per pass.

67. The solid state laser package of the claim 45 wherein the gain crystal assembly is fabricated using high density techniques.

68. The solid state laser package of claim 45 wherein the gain crystal assembly is fabricated by bonding wafers followed by polishing, coating and dicing wafers into a plurality of miniature crystal gain modules.

69. The solid state laser package of claim 45 wherein the power output from the pump diode is at least 250 mW.

70. The solid state laser package of claim 45 wherein the power output is at least 100 mW

71. The solid state laser package of claim 45 wherein the power output is at least 20 mW of visible light.

72. The solid state laser package of claim 45 wherein the resonator cavity is adapted to provide output in a single longitudinal mode.

73. The solid state laser package of claim 45 wherein the resonator cavity is adapted to provide output in a single transverse mode.

74. A modified semiconductor high heat load (HHL) package comprising,
A diode laser mounted on a heat sink platform and emitting radiation at a first wavelength,
A solid state laser microchip assembly pumped at said first wavelength and configured for emitting a second wavelength,
Wherein the micro-chip assembly is disposed within a resonator defined by a first input mirror and a second outcoupling mirror; and
Wherein said solid state laser microchip assembly and surrounding resonator mirrors are mounted on a shelf proximate to and extruding from the heat sink platform structure supporting the diode laser.

75. The modified HHL package of claim 74 further including means for stabilizing the power output of the resonator.

76. The modified HHL package of claim 75 wherein said power stabilization is carried out using a feedback control loop including a photodiode for sensing the power output.

77. The modified HHL package of claim 74 wherein said power stabilization means includes methods for controlling and adjusting the temperature of the gain crystal assembly.

78. The modified HHL package of claim 74 where the microchip assembly is mounted in a heatsink.

79. The modified HHL package of claim 74 further including means for cooling the gain crystal assembly to cryogenic temperatures.

80. The modified HHL laser package of claim 74 wherein the microchip assembly comprises a composite of at least two elements at least one of which is the active laser material

81. The modified HHL package of claim 80 wherein a second element of the microchip assembly is a nonlinear element

82. The modified HHL package of claim 74 wherein the microchip assembly comprises a composite of the active laser material and two nonlinear crystals.

83. The modified HHL package of claim 82 wherein the first nonlinear element is configured for second harmonic generation and the second harmonic crystal is configured for generating a third or fourth harmonic of the laser radiation.

84. The modified HHL package of claim 74 wherein the outcoupler mirror comprises a discrete optical element spaced apart from the gain crystal assembly and in alignment with the other resonator elements.

85. The modified HHL package of claim 74 wherein the resonator cavity further includes Q-switch means adapted to provide pulsed radiation.

86. The modified HHL package of claim 85 wherein said Q-switch comprises an active modulator.

87. The modified HHL package of claim 80 wherein the elements of the composite microchip assembly are joined using methods that reduce losses due to Fresnel reflections to less than 1% per pass.

88. The modified HHL package of the claim 74 wherein the microchip assembly is fabricated using high density techniques.

89. The modified HHL package of claim 74 wherein the microchip assembly is fabricated by dicing fabricated and coated crystal wafers into a plurality of miniature microchips.

90. The modified HHL package of claim 74 wherein the power of the pump diode is at least 2 W.

91. The modified HHL package of claim 74 adapted to produce power output of at least 0.5 W in a fundamental laser radiation.

92. The modified HHL package of claim 74 adapted to produce power output of at least 200 mW in the visible.

93. The modified HHL package of claim 74 adapted to produce power output of at least 50 mW in the UV.

94. The modified HHL package of claim 74 wherein the resonator cavity is adapted to provide output in a single longitudinal mode.

95. The modified HHL package of claim 74 wherein the resonator cavity is adapted to provide output in a single transverse mode.

96. A method of packaging a solid state micro-laser within a modified semiconductor laser package, comprising:
Removing the cap sealing the semiconductor laser package;
Extruding a shelf from the mounting platform supporting the semiconductor laser;
Mounting a miniature gain crystal resonator assembly comprising at least one gain element and two mirrors onto the shelf;
Aligning the semiconductor laser so it stably pumps the gain crystal;
Cementing the gain crystal resonator assembly onto the shelf;
Fabricating a modified cap containing an output window transparent to the output radiation from the gain crystal resonator;
Wherein the cap length is selected to accommodate the combined length of the semiconductor laser platform and the extruded shelf supporting the gain crystal resonator assembly; and
Replacing the modified cap to seal the package.

97. The method of claim 96 wherein the semiconductor laser package is a TO package.

98. The method of claim 96 wherein the semiconductor laser package is a HHL package.

99. The method of claim 96 wherein the gain crystal assembly is cooled using a TEC.

100. The method of claim 96 wherein the semiconductor laser is wavelength stabilized using a Bragg Grating.

101. The method of claim 96 wherein the gain crystal assembly comprises a composite of at least two elements.

102. The method of claim 96 wherein at least one of the resonator mirrors comprises a coating applied to the surface of the gain crystal assembly proximate to the semiconductor laser.

103. The method of claim 96 wherein cementing the laser crystal assembly to the shelf is performed using a glue.

104. The method of claim 96 wherein cementing the laser crystal assembly to the shelf comprises soldering.

105. The method of claim 96 wherein the laser crystal gain assembly is fabricated by dicing from a larger wafer

106. The method of claim 96 wherein the output window is AR coated at the output wavelength.

107. The method of claim 96 wherein the length of the gain material is selected to maximally absorb the semiconductor laser radiation.

108. The method of claim 96 wherein the resultant solid state micro-laser package has a volume smaller than about 1 cubic centimeter

109. A method to mass produce miniaturized solid state lasers designed to provide at least one output wavelength and comprising the steps of:
Fabricating and polishing wafer composites comprising at least one active laser gain material,
Coating the wafer to minimize losses and provide selected reflection or transmission properties at the at least one output wavelength,
Dicing the wafer into a plurality of usable microchip crystal gain assemblies,
Mounting each crystal gain assembly in a modified semiconductor laser package on a shelf protruding from the semiconductor laser mounting platform,
Using the output from the semiconductor laser to pump the crystal gain assembly,
Aligning the crystal gain assembly to optimize the output wavelength, and
Securing the crystal gain assembly to the shelf.

110. The method of claim 109 wherein the wafer composite comprises at a second nonlinear optical element.

111. The method of claim 110 wherein the wafer composite is produced by a cementing process using glue transparent to the output wavelength.

112. The method of claim 109 wherein the wafer composite is produced using an optical contacting process.

113. The method of claim 109 wherein the wafer composite is produced using a diffusion bonding process.

114. The method of claim 109 wherein at least one additional optical element is mounted onto the shelf supporting the crystal gain assembly.

115. The method of claim 114 wherein the optical element is an outcoupler mirror.
